(19) United States
(12) Patent Application Publication
(10) Pub. No.: US 2006/0286717 A1
(43) Pub. Date: Dec. 21, 2006

(54) Stacked microelectronic assemblies having basal compliant layers

(75) Inventors: Vernon Solberg, Saratoga, CA (US); Pieter H. Bellaar, Baambrugge (NL); Young-Gon Kim, Cupertino, CA (US); Belgacem Haba, Cupertino, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/123,989

(22) Filed: May 6, 2005

(51) Int. Cl. H01L 21/00

(52) U.S. Cl. 438/113

(57) ABSTRACT

A method of making a stacked microelectronic assembly includes providing a flexible substrate having first and second ends, the flexible substrate having a plurality of attachment sites located between the first and second ends thereof including a first one of the attachment sites located adjacent the first end of the flexible substrate, the flexible substrate including conductive terminals accessible at a surface of the flexible substrate and wiring connected to the terminals, providing a compliant layer over the first attachment site, assembling a plurality of microelectronic elements over the attachment sites, wherein a first one of the microelectronic elements engages the compliant layer and is movable relative to the flexible substrate, electrically interconnecting the microelectronic elements and the wiring, folding the flexible substrate and stacking at least some of the microelectronic elements in generally vertical alignment with one another so that the first one of the microelectronic elements engaging the compliant layer is disposed at a bottom of the stacked assembly, and maintaining the stacked microelectronic elements in the substantially vertical alignment, wherein the conductive terminals are exposed at the bottom end of the stacked assembly.

### FIELD OF THE INVENTION

The present invention relates to microelectronic assemblies and more particularly relates to stacked microelectronic assemblies having compliant layers.

### BACKGROUND OF THE INVENTION

Semiconductor chips are commonly provided as individual, prepackaged units. A standard chip has a flat, rectangular body with a large front face having contacts for connection to the internal circuitry of the chip. Each individual chip is typically mounted to a substrate or chip carrier, which in turn is mounted on a circuit panel such as a printed circuit board. Considerable effort has been devoted towards development of so-called “multichip packages” in which several chips having related functions are attached to a common circuit panel and protected by a common package. This approach conserves some of the space which is ordinarily wasted by individual chip packages. However, most multichip packages utilize a single layer of chips positioned side-by-side on a surface of a planar circuit panel.

Another space conserving design is commonly referred to as a “flip chip” package in which the front face of a semiconductor chip confronts a top surface of a circuit panel and the contacts on the chip are bonded to the circuit panel by solder balls or other connecting elements. The “flip chip” design provides a relatively compact arrangement, with each chip occupying an area of the circuit panel equal to or slightly larger than the area of the chip. As disclosed, in commonly assigned U.S. Pat. Nos. 5,148,265 and 5,148,266, the disclosures of which are hereby incorporated by reference herein, certain innovative mounting techniques offer compactness approaching or equaling that of “flip chip” packages without the reliability and testing problems commonly encountered in that approach.

Another package design for saving space in electronic components is commonly referred to as a “stacked” arrangement, i.e., an arrangement where several chips are placed one atop the other. One such stacked arrangement is disclosed in commonly assigned U.S. Pat. No. 5,347,159, the disclosure of which is hereby incorporated by reference herein, wherein chips are stacked one atop the other and interconnected with one another by conductors on so-called “wiring films” associated with the chips.

Another stacked arrangement is disclosed in preferred embodiments of commonly assigned U.S. Pat. No. 5,861,666, the disclosure of which is hereby incorporated by reference herein. One aspect of the invention in the '666 patent provides a plurality of semiconductor chip assemblies whereby each assembly includes an interposer and a semiconductor chip mounted thereto. Each interposer also includes a plurality of leads electrically interconnecting the chip and the interposer. The assembly also includes compliant layers disposed between the chips and the interposers so as to permit relative movement of the chips and interposers to compensate for thermal expansion and contraction of the components. As is well known to those skilled in the art, semiconductor chips dissipate electrical power as heat during operation. When chips are stacked one atop the other, it is difficult to dissipate the heat generated by the chips in the middle of the stack. Consequently, the chips in such a stack may undergo substantial thermal expansion and contraction during operation. This, in turn, imposes significant mechanical stress on the interconnecting arrangements and on the mountings which physically retain the chips.

Still another “stacked” arrangement is disclosed in commonly assigned U.S. Pat. No. 6,225,688, the disclosure of which is hereby incorporated by reference herein. Referring to FIGS. 1 and 2 of the '688 patent, a microelectronic assembly includes a flexible substrate 10 having a wiring layer 12 and leads 14 having ends 16 extending to a plurality of attachment sites 18. The leads 14 have connections sections configured for bonding at each attachment site. The plurality of attachment sites 18 and the ends 16 of the leads 14 extending to the attachment sites are provided at a first surface 20 of the flexible substrate 10. The attachment sites 18 are grouped in pairs 25A and 25B which are spaced on the flexible substrate 10. The flexible substrate 10 includes conductive terminals 22 accessible at the second surface 24 thereof. The conductive terminals 22 are connected with the wiring layer 12 and with at least some of the leads 14.

FIGS. 3 and 4A show a plurality of microelectronic elements 26 assembled to the attachment sites 18. In certain preferred embodiments, the chips are fully packaged prior to attachment to the “folding substrate.” As a result, if one chip is defectively packaged, the entire module does not need to be replaced. In one embodiment, each microelectronic element 26 preferably includes a semiconductor chip having a front face 28 with one or more electrical contacts 30 thereon. Each semiconductor chip 26 also includes a back surface 32. Before the chips 26 are assembled, a plurality of compliant pads 31 are provided over each attachment site 18. The compliant pads 31 define channels 35 running therebetween, such as disclosed in commonly assigned U.S. Pat. No. 5,659,952, the disclosure of which is hereby incorporated by reference herein. Next, the front face 28 of the semiconductor chip 26 is abutted against the compliant pads 31 at the attachment site 18 and the contacts 30 on the chip are aligned with the leads 14 extending to each attachment site, and the leads 14 are electrically interconnected with the contacts 30. After the semiconductor chips 26 have been assembled to the attachment sites 18 and bonded to the leads 14, the wiring layer 12 interconnects the semiconductor chips 26 with the conductive terminals 22 at the second surface 26 of the flexible substrate 20.

Referring to FIG. 4B, a curable liquid encapsulant 33 is applied around at least the perimeter of the chips 26. The encapsulant 33 flows between the front face 28 of the chip 26 and the attachment site 18, through the channels 35 between the plurality of compliant pads 31 and around the leads 14 bonded to the contacts 30. The encapsulant 33 is preferably cured using energy, such as heat, to provide a compliant interface between each chip 26 and the flexible substrate 10.

Referring to FIG. 5, the flexible substrate 10 is then folded in a gentle zig-zag or an “S” shaped pattern to stack the chips in vertical alignment with one another, whereby portions of the flexible substrate 10 overlap. During the folding step, the back surfaces 32 of paired semiconductor chips 26 are juxtaposed with one another. In order for the back surfaces 32 of the pairs of microelectronic elements 26 to be juxtaposed with one another without stretching or tearing the flexible substrate 10, the attachment sites 18 must be spaced sufficiently apart so that there is adequate slack in the flexible substrate 10 between the paired chips 26. The particular embodiment shown in FIG. 5 includes a first pair 34 of semiconductor chips 26 juxtaposed back-to-back to one another and sandwiched between a first section 38 of the flexible substrate 10. The flexible substrate 10 is then folded back over upon itself at an intermediate section 40 thereof, whereby portions of the flexible tape 10 are juxtaposed with one another. Next, the back surfaces 32 of a second pair 36 of semiconductor chips 26 are juxtaposed with one another. The final stacked assembly shown in FIG. 5 includes the first and second pairs 34 and 36 of chips 26 whereby the first pair 34 is provided over the second pair 36 and the two pairs 34 and 36 are substantially in vertical alignment with one another. A compliant layer is preferably disposed between each chip and the attachment site on which the chip is mounted.

Although the approaches set forth above offer useful ways of making stacked assemblies, still other methods would be desirable. Specifically, stacked assemblies having smaller footprints and lower silhouettes are highly desirable.

### SUMMARY OF THE INVENTION

In accordance with certain preferred embodiments of the present invention, a method of making a stacked microelectronic assembly includes providing a flexible substrate having first and second ends, the flexible substrate having a plurality of attachment sites located between the first and second ends thereof with a first one of the attachment sites located adjacent the first end of the flexible substrate, the flexible substrate including conductive terminals accessible at a surface of the flexible substrate and wiring connected to the terminals, and providing a compliant layer over the first attachment site. The method also includes assembling a plurality of microelectronic elements over the attachment sites, whereby a first one of the microelectronic elements engages the compliant layer and is movable relative to the flexible substrate, electrically interconnecting the microelectronic elements and the wiring, and folding the flexible substrate so as to stack at least some of the microelectronic elements in generally vertical alignment with one another so that the first one of the microelectronic elements engaging the compliant layer is disposed at a bottom of the stacked assembly. The stacked microelectronic elements are desirably maintained in the substantially vertical alignment so that the conductive terminals are exposed at the bottom end of the stacked assembly.

In certain preferred embodiments, the wiring includes flexible leads extending to the attachment sites, and the electrically interconnecting step includes electrically connecting the microelectronic elements and the flexible leads. The wiring preferably interconnects at least some of the microelectronic elements with one another.

The flexible substrate desirably includes a polymeric material having a thickness between approximately 25-75 microns. During the assembly step, the contacts on front faces of the microelectronic elements are preferably aligned with ends of the flexible leads at the attachment sites. In certain preferred embodiments, the step of providing a compliant layer desirably includes providing a plurality of compliant pads at the one of the attachment sites before the assembling step, the compliant pads defining channels therebetween. A curable liquid encapsulant may be introduced between the plurality of compliant pads and through the channels between the compliant pads. The curable liquid encapsulant may be cured to provide the compliant layer.

In certain preferred embodiments, the stacking step includes grouping at least some of the microelectronic elements in pairs and juxtaposing the paired microelectronic elements with one another. Each of the microelectronic elements desirably includes a front contact bearing surface and a back surface remote therefrom, at least some of the microelectronic elements being assembled to the flexible substrate with the front contact bearing surfaces facing toward the attachment sites and the back surfaces facing away from the attachment sites. The juxtaposing step desirably includes abutting the back surfaces of the paired microelectronic elements with one another. The method may also include applying an adhesive between the back surfaces of the paired microelectronic elements before the abutting step. The adhesive may include a thermally conductive adhesive.

After the flexible substrate has been folded so as to generally align the microelectronic elements in a vertical configuration, a support structure may be used for maintaining the assembly in a stacked configuration. In certain preferred embodiments, the support structure includes a bracket abutting against a top of the stacked microelectronic elements. In certain preferred embodiments, thermally conductive sheets may be provided between the back surfaces of the paired microelectronic elements for removing heat from the assembly.

In other preferred embodiments of the present invention, a stacked microelectronic assembly includes a flexible substrate having a plurality of attachment sites, the flexible substrate including conductive terminals accessible at a surface thereof, wiring connected to the terminals accessible at a surface thereof, wiring connected to the terminals and flexible leads connected to the wiring and extending to the attachment sites, and a plurality of microelectronic elements assembled to the attachment sites and electrically connected to the leads. The stacked microelectronic assembly may also include a compliant layer disposed between one of the microelectronic elements and the attachment site associated therewith, whereby the one of the microelectronic elements is movable relative to the flexible substrate. The flexible substrate is preferably folded so that at least some of the microelectronic elements are stacked in substantially vertical alignment with one another, the one of the microelectronic elements being positioned at a bottom end of the stacked assembly, and a securing element maintaining the stacked microelectronic elements in substantially vertical alignment with one another, whereby the conductive terminals are exposed at the bottom end of the stacked assembly.

In other preferred embodiments of the present invention, a method of making a stacked microelectronic assembly includes providing a flexible substrate having a plurality of attachment sites, the flexible substrate including conductive terminals accessible at a surface thereof and wiring connected to the terminals, and assembling a plurality of microelectronic elements over the attachment sites. The method also desirably includes electrically interconnecting the microelectronic elements and the wiring, providing an encapsulant layer between the microelectronic elements and the attachment sites, folding the flexible substrates and stacking at least some of the microelectronic elements in generally vertical alignment with one another, wherein a first one of the microelectronic elements is disposed at a bottom of the stacked assembly, and whereby a region of the encapsulant layer adjacent the first microelectronic element is more compliant than the encapsulant layer adjacent the other microelectronic elements. The method also desirably includes maintaining the stacked microelectronic elements in the substantially vertical alignment, with the conductive terminals exposed at the bottom of the stacked assembly.

In yet another preferred embodiments of the present invention, a stacked microelectronic assembly includes a dielectric element having an upwardly-facing first surface and a downwardly-facing second surface and having conductive terminals exposed at the second surface, and a first microelectronic element overlying the first surface of the dielectric element. The stacked microelectronic assembly also preferably includes a second microelectronic element overlying the first microelectronic element, and a first encapsulant layer between the first microelectronic element and the first surface of the dielectric layer. The stacked microelectronic assembly also desirably includes a second encapsulant layer between the first and second microelectronic elements, whereby the first encapsulant layer is more compliant than the second encapsulant layer so that one or more of the conductive terminals underlying the first microelectronic element are movable relative to the first microelectronic element.

In further preferred embodiments of the present invention, a microelectronic assembly includes a plurality of microelectronic subassemblies, each subassembly including a dielectric substrate having a top surface, a microelectronic element mounted over the dielectric substrate, whereby the microelectronic element is electrically interconnected with the dielectric substrate, and an encapsulant layer provided over the top surface of the dielectric substrate between the microelectronic element and the dielectric substrate, with the microelectronic subassemblies stacked one atop another. The encapsulant layer of the bottom one of the stacked subassemblies is more compliant than the encapsulant layers of the stacked subassemblies above the bottom subassembly.

In still other preferred embodiments of the present invention, a microelectronic assembly with a basal compliant layer includes microelectronic subassemblies stacked one atop another, each subassembly having a dielectric substrate having a top surface, a microelectronic element mounted over the top surface of the dielectric substrate, an encapsulant layer between the microelectronic element and the top surface of the dielectric substrate, wherein the encapsulant layer of a bottom one of the stacked microelectronic subassemblies is more compliant than the encapsulant layers of the other microelectronic subassemblies of the stacked microelectronic assembly.

In certain preferred embodiments, two or more of the stacked microelectronic subassemblies are electrically interconnected with one another. The dielectric substrate of the bottom subassembly preferably has conductive terminals accessible at a bottom surface thereof. In other preferred embodiments, at least one of the stacked subassemblies is electrically interconnected with conductive terminals at the bottom of the assembly. The encapsulant layer of the bottom subassembly may include a plurality of compliant pads.

Although the present invention is not limited by any particular theory of operation, it is believed that providing a compliant layer for the bottom-most chip of a stacked assembly, while not providing a compliant layer for the remaining chips in the stack, will minimize the overall height of the stacked assembly while allowing movement between the conductive terminals at the bottom of the package and the bottom-most chip during thermal cycling.

These and other preferred embodiments of the present invention will be described in more detail below.

### BRIEF DESCRIPTION OF THE DRAWINGS

FIG. 1 shows a diagrammatic top view of one stage of a method of making a conventional stacked microelectronic assembly.

FIG. 2 shows a side view of FIG. 1.

FIGS. 3-5 show still further stages of a method of making a conventional stacked microelectronic assembly.

FIGS. 6 and 7 show a method of making a stacked microelectronic assembly having a basal compliant layer, in accordance with certain preferred embodiments of the present invention.

FIG. 8 shows a side view of a stacked microelectronic assembly having a basal compliant layer, in accordance with other preferred embodiments of the present invention.

FIGS. 9 and 10 show a side view of a method of making a stacked microelectronic assembly having a basal compliant layer, in accordance with still other preferred embodiments of the present invention.

FIGS. 11 and 12 shows a method of making a stacked microelectronic assembly having a basal compliant layer, in accordance with still other preferred embodiments of the present invention.

FIG. 13 shows a side view of a stacked microelectronic assembly having a basal compliant layer, in accordance with another preferred embodiments of the present invention.

FIG. 14 shows a side view of a stacked microelectronic assembly having a basal compliant layer, in accordance with still another preferred embodiment of the present invention.

FIGS. 15 and 16 show a method of making a stacked microelectronic assembly having a basal compliant layer, in accordance with yet further preferred embodiments of the present invention.

FIGS. 17 and 18 show a method of making a stacked microelectronic assembly having a basal compliant layer, in accordance with still further preferred embodiments of the present invention.

FIGS. 19 and 20 show a method of making a stacked microelectronic assembly, in accordance with other preferred embodiments of the present invention.

FIG. 21 shows a stacked microelectronic assembly having a basal compliant layer, in accordance with other preferred embodiments of the present invention.

FIGS. 22 and 23 show a method of making a stacked microelectronic assembly having a basal compliant layer, in accordance with yet further preferred embodiments of the present invention.

FIG. 24 show a stacked microelectronic assembly having a basal compliant layer, in accordance with other preferred embodiments of the present invention.

FIGS. 25-27 show a method of making a stacked microelectronic assembly having a basal compliant layer, in accordance with other preferred embodiments of the present invention.

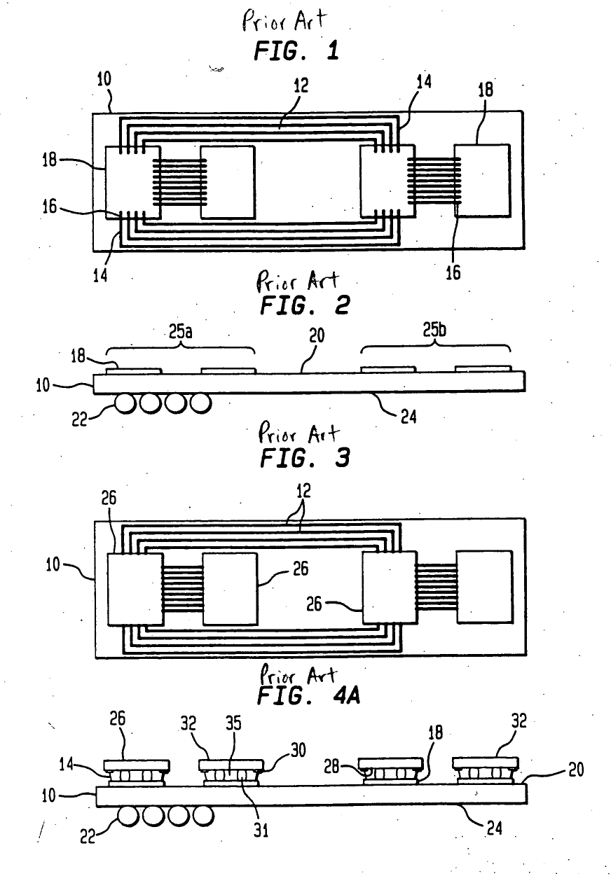

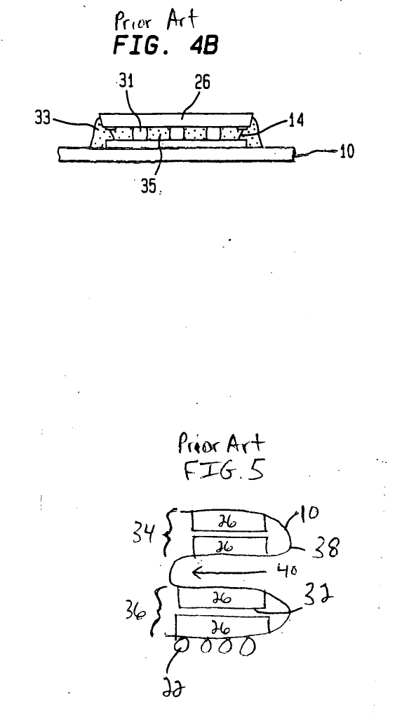

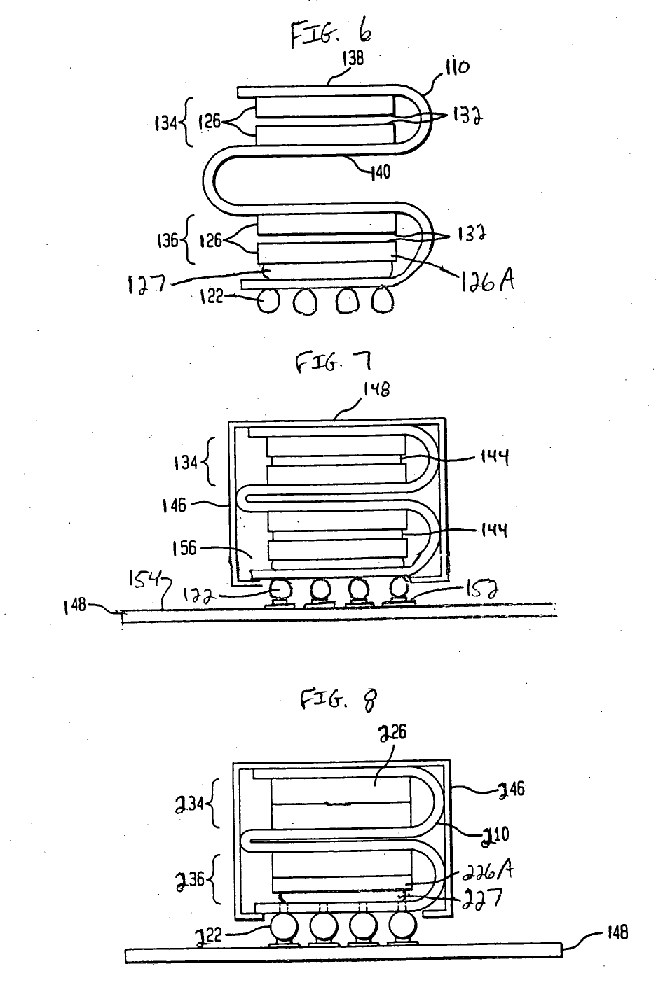

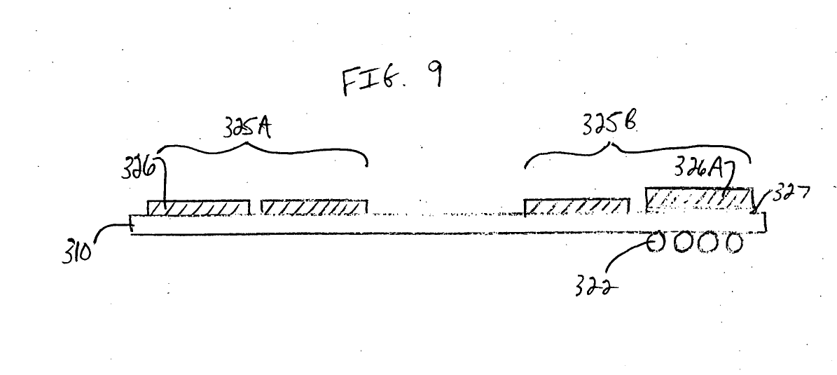

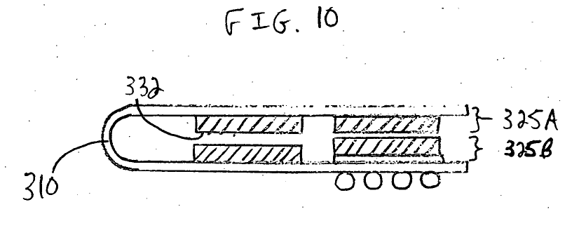

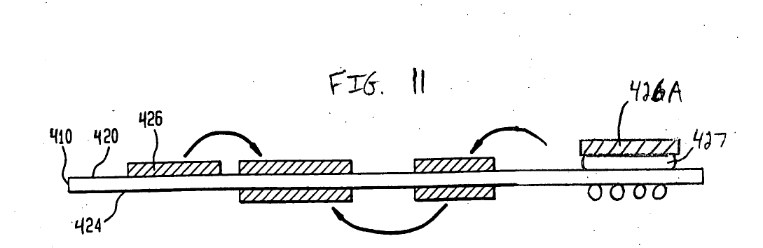

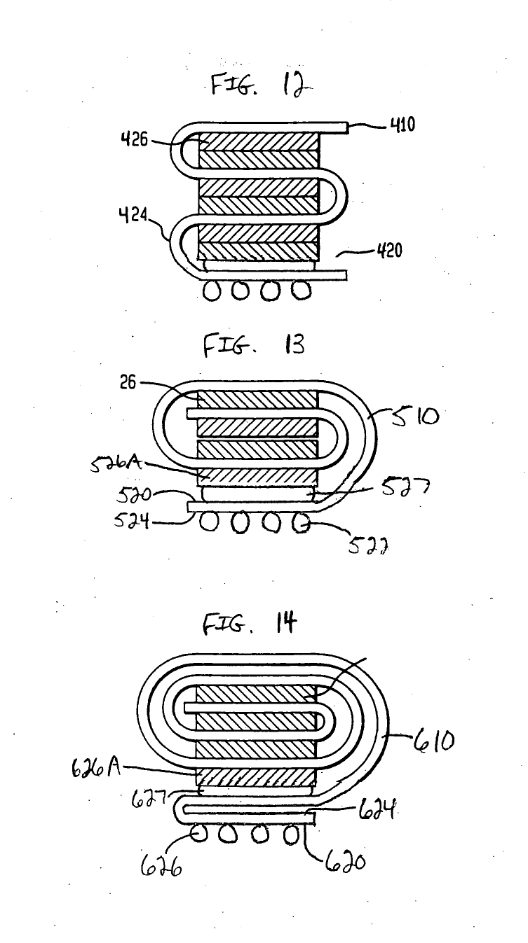

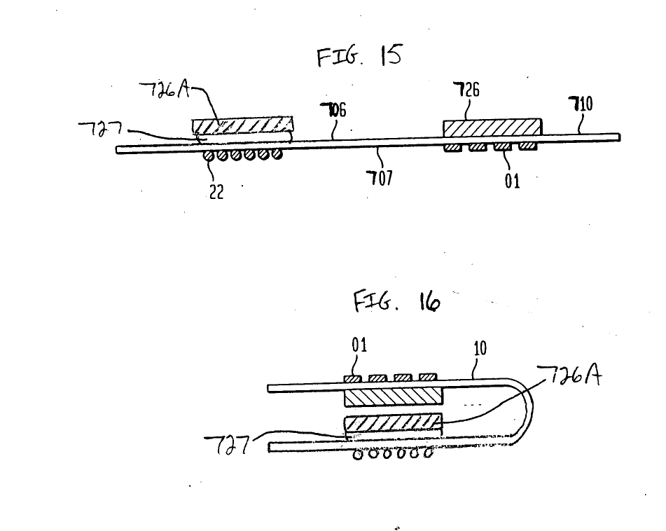

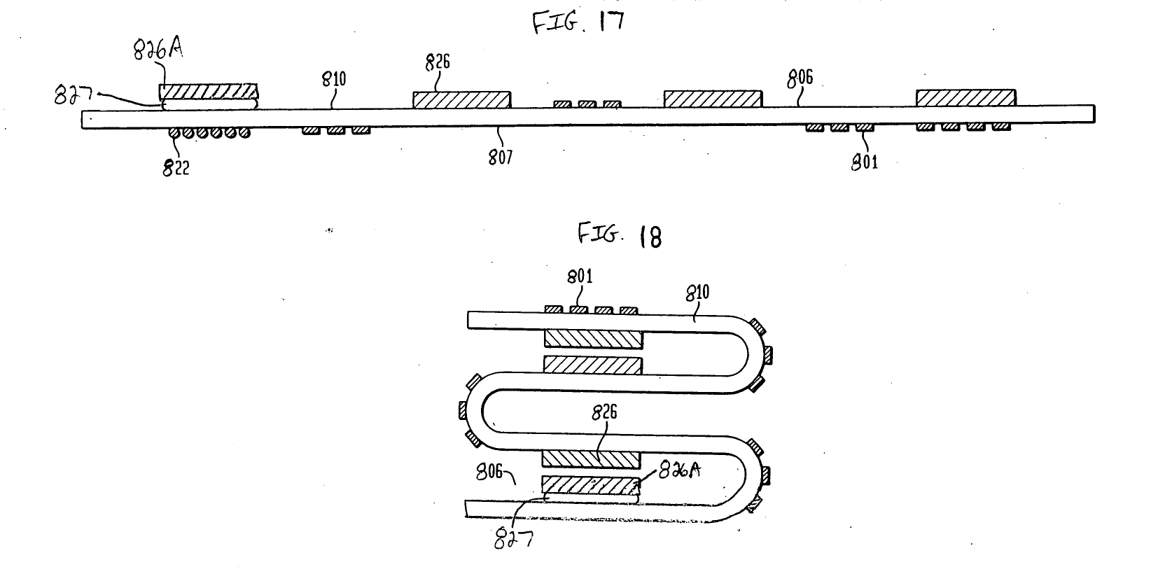

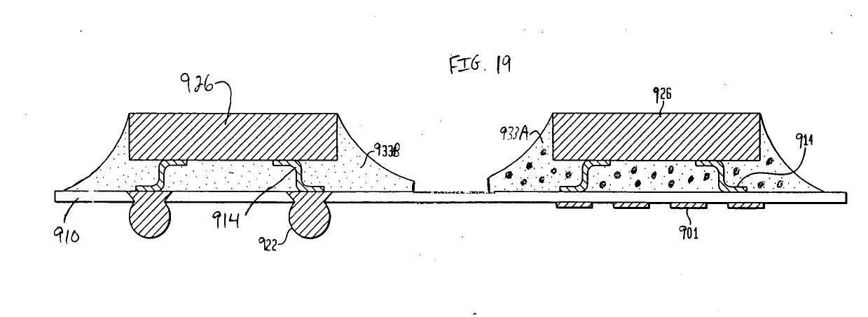

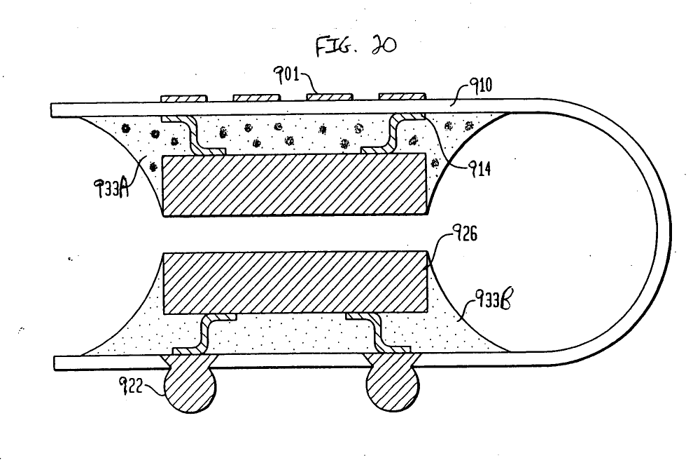

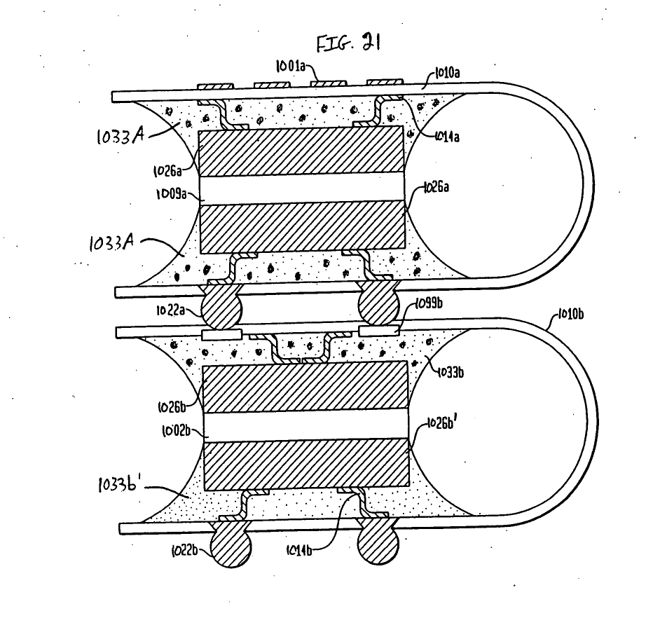

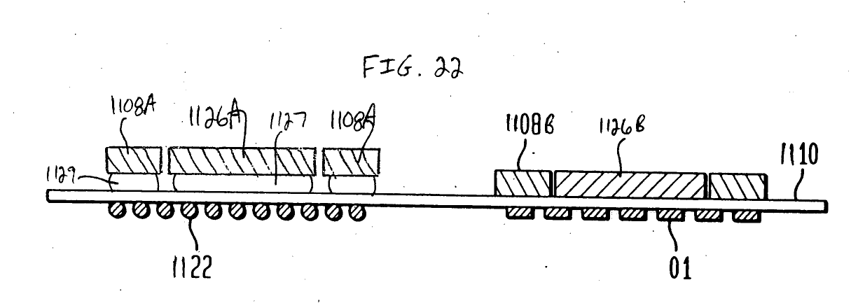

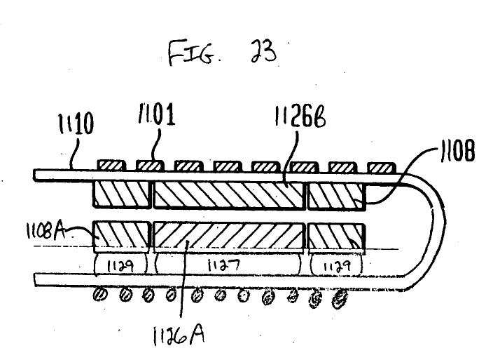

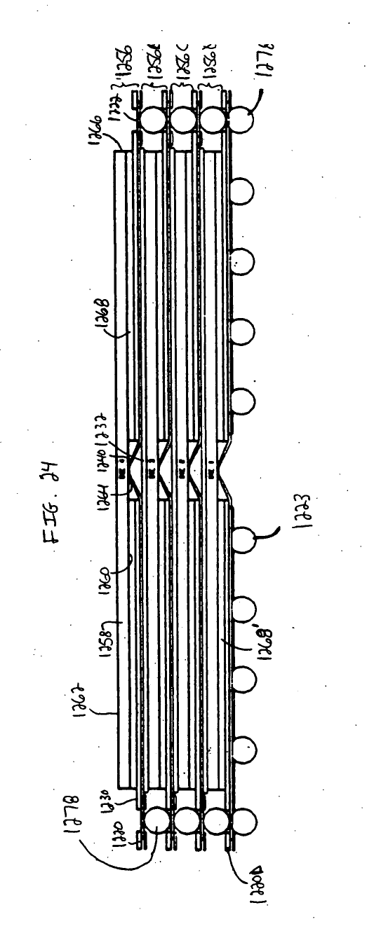

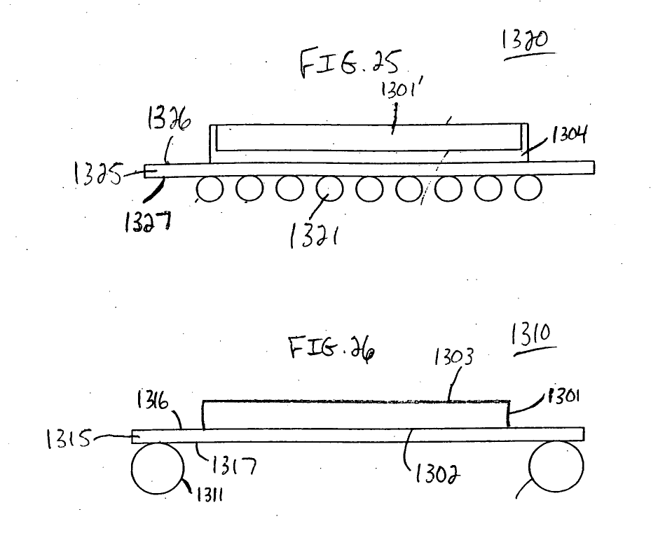

### DETAILED DESCRIPTION

As noted above, the present invention is related to providing a basal compliant layer for a stacked microelectronic assembly. In certain preferred embodiments, only the bottom microelectronic element in a stack has a compliant layer for enabling movement during thermal cycling, while the microelectronic elements above the bottom microelectronic element do not have a compliant layer. This design reduces the overall height of the stacked package, while allowing movement between the bottom-most microelectronic element and the conductive terminals of the assembly.

Referring to FIGS. 6 and 7, in certain preferred embodiments of the present invention, a stacked assembly includes a plurality of chips 126 mounted to a flexible substrate 100. The substrate 100 is folded to align the chips 126 in a generally vertical configuration. An adhesive 144, such as a thermally conductive adhesive, is provided between juxtaposed back surfaces 132 of semiconductor chips 126. The adhesive 144 bonds the back surfaces of the juxtaposed chips 126 together to provide stability to the stacked assembly. The thermally conductive adhesive 144 preferably promotes even distribution of heat in the stacked chips 126, and thus limits the temperature rise in the hottest chips. The thermally conductive adhesive promotes conduction in the vertical direction within the stack; i.e., transfers the heat to the top and bottom of the stacked assembly for dissipation outside the assembly. To provide additional support for the assembly, a mechanical element 146, such as a bracket, is placed over the vertically aligned chips 126 so that the bracket 146 abuts against the top 148 of the aligned chips 126. Preferably, the bracket 146 does not include any side walls so that cooling air may freely interact with the exposed surfaces of the semiconductor chips 126. In other embodiments, the bracket 146 may include one or more side walls having openings therein for enabling cooling air to flow therethrough. Conductive terminals 122 are exposed at the bottom of the final assembly so that the chips 126 may be electrically interconnected with an external circuit element 148, such as a printed circuit board. A compliant layer 127 is desirably provided between bottom chip 126A and terminals 122 to provide for relative movement of the terminals 122 and bottom chip 126A during thermal cycling of the stacked assembly. Fusible material is preferably provided on the conductive terminals 122 for bonding the terminals 122 to conductive pads 152 located at a top surface 154 of the printed circuit board 148.

FIG. 8 shows another preferred embodiment of the present invention wherein a thermally conductive adhesive is not used between the back surfaces of the pairs of chips 226. In this particular embodiment, the semiconductor chips 226 are assembled and electrically interconnected with a flexible substrate 210. A basal compliant layer 227 is desirably provided between bottom-most chip 226A and conductive terminals 222 to allow movement of the terminals 222 relative to the bottom-most chip 226A during thermal cycling. The flexible substrate 210 is folded so that the chips 226 are stacked in vertical alignment with one another and so that the back surfaces of pairs 234, 236 are juxtaposed with one another. While the chips 226 are held in vertical alignment, a securing element 246, such as the bracket described above, is placed over the top of the stack. The securing element 246 abuts against the top of the stack to maintain the stacked assembly in vertical alignment. The assembly may then be electrically interconnected with an external circuit element 248 using the methods described above.

FIGS. 9 and 10 show further embodiments of the present invention whereby chips 326 are stacked in both vertical alignment and side-by-side. For example, first and second groups of microelectronic elements 325A, 325B are assembled to the flexible substrate 310 so that the chips 326 within the respective first and second groups 325A, 325B are in close proximity with one another. A compliant layer 327 is provided between chip 326A and conductive terminals 322 to provide for movement of chip 326A relative to terminals 322 during thermal cycling. As shown in FIG. 10, the flexible substrate 310 is folded over so that the back surfaces 332 of the chips 326 in the first group 325A are adjacent the back surfaces 332 of the chips 326 in the second group 325B. Thus, although the chips 326 in any one group are disposed side-by-side, the chips in the different groups are stacked in vertical alignment, one atop the other, to provide a stacked assembly which will save space on a circuit board. In certain preferred embodiments, the back surfaces of the chips may be in contact with one another.

FIGS. 11 and 12 show still further embodiments of the present invention whereby some of the chips 426 are assembled to the first surface 420 of the flexible substrate 410 and some of the chips 426 are assembled to the second surface 424 of the flexible substrate 410. A compliant layer 427 is provided between bottom-most chip 426A and terminals 422 to provide for relative movement during thermal cycling. Referring to FIG. 12, the flexible substrate 410 is then folded in an “S”-shaped or gentle zig-zag configuration to provide a stacked assembly whereby the chips are in substantial vertical alignment with one another. The stack is maintained in vertical alignment using the thermally conductive adhesive and/or the mechanical element discussed above. Flexible metal sheets (not shown) may be placed between the microelectronic elements to transfer heat from the chips.

Referring to FIGS. 13 and 14, in yet further preferred embodiments of the present invention, the conductive terminals can be accessible at either the first surface or the second surface of the flexible substrate. A compliant layer 527 is preferably provided between bottom-most chip 526A in the stack and conductive terminals 522 to provide for relative movement during thermal cycling. After the chips are assembled to the flexible substrate, the flexible substrate is folded so that the conductive terminals are exposed at the bottom of the stack so the assembly may be electrically connected to an external circuit element, such as a printed circuit board. FIG. 13 shows a flexible substrate 510 having the chips 526 assembled to both the first and second surfaces 520, 524 of the flexible substrate 510 and the conductive terminals 522 being accessible at the second surface 524 of the flexible substrate 510. FIG. 14 shows another embodiment whereby a flexible substrate 610 has chips assembled to both the first and the second surfaces 620, 624 of the flexible substrate 610; however, the conductive terminals 622 are accessible at the first surface 620 of the flexible substrate 610. A compliant layer 627 is provided between bottom-most chip 626A and conductive terminals 622 to provide for movement during thermal cycling. In this particular embodiment, an extra fold is provided in the flexible substrate 610 when forming the stacked assembly so that the conductive terminals 622 are exposed at the bottom of the assembly.

FIGS. 15 and 16 show yet another embodiment of the present invention whereby the flexible substrate 710 includes a plurality of electrically conductive test contacts 701. The test contacts 701 are connected to the wiring layer (not shown) and at least some of the leads (not shown) which interconnect the chips 726 with the flexible substrate 710. The test contacts may be disposed on either the first surface 706 of the flexible substrate or the second surface 707. Referring to FIG. 16, a compliant layer 727 is provided between bottom-most chip 726A in the stack and conductive terminals 722 to provide for relative movement of chip 726A to terminals 727 during thermal cycling. As depicted in FIGS. 17 and 18, the test contacts may be disposed on both the first surface 806 and the second surface 807. As depicted in FIG. 18, after the flexible substrate is folded, the test contacts are preferably exposed on the top end of the assembly. By incorporating test contacts, the assembly may be tested before, during or after the assembly is connected to a larger circuit panel such as a printed circuit board. Having the test contacts disposed on the top end of the assembly facilitates this testing because the test contacts are more easily accessed. A compliant layer 827 is provided between bottom-most chip 826A in the stack and conductive terminals 822 to provide for relative movement of chip 826A to terminals 827 during thermal cycling.

FIGS. 19 and 20 depict another embodiment of the present invention whereby the assembly includes two or more encapsulant layers 933A, 933B having different levels of compliancy. Encapsulant layer 933B is preferably more compliant than encapsulant layer 933A. The encapsulant is disposed between the face of each chip and the flexible substrate. The encapsulant is typically formed by applying a curable liquid encapsulant composition around the perimeter of the chips and then curing the composition to form cured encapsulant layers 933A, 933B. A plurality of complaint pads (not shown) may be disposed on the flexible substrate 910 before the liquid curable encapsulant is disposed on the flexible substrate. The curable liquid encapsulant composition is dispensed onto the flexible substrate 910 after the leads 914 are interconnected to the semiconductor chips 926 and before the substrate 910 is folded. The liquid curable encapsulant composition is desirably cured before the flexible substrate 910 is folded.

FIG. 22 depicts still another embodiment of the present invention. The multi-part stacked microelectronic assembly includes a first stacked microelectronic assembly and a second stacked microelectronic assembly which is interconnected with the first stacked microelectronic assembly. The first stacked microelectronic assembly includes a plurality of vertically aligned first semiconductor chips 1026a. The first assembly also includes a first flexible substrate 1010a which is disposed in a folded configuration and which has a plurality of electrically conductive first terminals 1022b, and first wiring (not shown) including a plurality first leads 1014a which interconnect the first chips 1026a with first terminals 1022a. The first stacked microelectronic assembly may also include a first adhesive 1009a disposed between the back surfaces of vertically aligned first chips 1026a, or another first securing element for maintaining the vertical alignment of such first chips. The first assembly also includes a plurality of electrically conductive test contacts 1001a disposed on the first flexible substrate 1010a. Such test contacts are electrically interconnected to first chips 1026a.

The second stacked microelectronic assembly includes a plurality of vertically aligned semiconductor chips 1026b and 1026b′. The second assembly also includes a second flexible substrate 1010b which is disposed in a folded configuration and which has a plurality of electrically conductive second terminals 1022b, and second wiring (not shown) including a plurality second leads 1014b which interconnect the second chips 1026b, 1026b′ with second terminals 1022b. The second assembly may also include a second adhesive 1009b disposed between the back surfaces of vertically aligned second chips 1026b, 1026b′ or another securing element for maintaining the vertical alignment of such second chips. The second assembly also includes a plurality of electrically conductive connection pads 1099b disposed on second substrate 1010b. The first and the second stacked assemblies are interconnected to form a multi-part stacked assembly aligning and interconnecting the first terminals 1022a of the final assembly with the connection pads 1099b of the second assembly. The bottom-most encapsulant layer 1033b′ is more compliant than the other encapsulant layers 1033a, 1033b of the stack so as to provide for relative movement between second terminals 1022b and bottom-most chip 1026b′ during thermal cycling.

FIGS. 22 and 23 show yet another preferred embodiment of the present invention whereby a support element is disposed around one or more of the microelectronic elements 1126, with the terminals 1122 and/or test contacts 1101 disposed on an area of the flexible substrate 1110 that is greater than the foot print of the adjacent microelectronic element 1126A, 1126B. The terminals or test contact may be disposed in such an area because, for example, of a need to match the arrangement of terminals with the arrangement of connection pads on a printed circuit board, because the number of terminals or text contacts needed is greater than the number that can be accommodated in an area that corresponds to the foot print of the microelectronic element or because of a desire to increase the pitch, or center to center, distance between adjacent terminals or test contacts. When some of the terminals and/or contacts are disposed in an area outside the footprint of the adjacent microelectronic element, it may be desirable to incorporate one or more support elements, such as support rings 1108, into the assembly. As depicted in FIG. 22, a first support ring 1108A is disposed around the bottom-most microelectronic element 1126A and a second support ring 1108B is disposed around the top microelectronic element 1126B. Such support rings may be made of any relatively rigid material such as a metal or a plastic. Metal or epoxy support rings are preferred. The support rings help to maintain the planarity of the assembly, especially when the assembly is incorporated into a larger circuit element, such as a printed circuit board, and/or when the test contacts are engaged with a testing device. In preferred embodiments, if one of the microelectronic elements is surrounded by a support element, each of the microelectronic elements is surrounded by a support element. A compliant layer 1127 is preferably provided between bottom-most chip 1126A in the stack and conductive terminals 1122 to provide for relative movement of chip 1126A to terminals 1127 during thermal cycling. A second compliant layer 1129 may be provided between support ring 1108A and conductive terminals 1122.

Certain preferred embodiments of the present invention include stacked assemblies such as those disclosed in commonly assigned U.S. patent application Ser. No. 10/267,450, filed Oct. 9, 2002, the disclosure of which is hereby incorporated by reference herein. Referring to FIG. 24, a stacked chip assembly includes a plurality of units 1256A-1256D. Each such unit includes a panel or chip carrier 1220 and a chip 1258 associated with that panel. Each such chip has a front or contact bearing surface 1260 and a rear surface 1262. The front surface 1260 of each chip has contacts 1264 arranged in rows adjacent the center of the chip. The chip also has edges 1266 bounding the front and rear surfaces 1262. The thickness of the chip (the dimension between the front surface 1260 and back surface 1262) typically is substantially smaller than the other dimensions of the chip. For example, a typical chip may be about 100-200 microns thick and may have horizontal dimensions (in the plane of the front and rear surfaces) of about 0.5 cm or more. The front surface 1260 of the chip faces towards the second surface 1230 of the associated panel 1220.

An encapsulant layer 1268, such as a layer of adhesive, is disposed between the chip 1258 and the panel 1220 of each unit 1256. The encapsulant layer 1268′ of the bottom-most unit 1256D is preferably more compliant than the encapsulant layers 1268 of the other units 1256A-1256C stacked above the bottom-most unit 1256D. Each encapsulant layer 1268 preferably defines an aperture in alignment with the bond window. Encapsulant layer 1268 may be provided by applying a liquid or gel material between the chip and the panel at the time of assembly or by providing a porous layer such as an array of small resilient elements between the layers and injecting a flowable material into such layer as taught, for example, in certain embodiments of U.S. Pat. Nos. 5,659,952 and 5,834,339, the disclosures of which are hereby incorporated by reference herein. Preferably, however, the encapsulant layer is provided as one or more solid or semi-solid pads having substantially the same horizontal extent as the desired encapsulant layer in the final product. These pads are placed between the chip and panel during assembly. For example, the pad may be pre-assembled to the panel or to the chip before the chip is juxtaposed with the panel. Such a solid or semi-solid pad can be placed quite accurately in relation to the chip and the panel. This helps to assure that the pad does not cover terminals 1222, even where there is only a small clearance between the nominal position of the pad edge and the terminals. Such a pad may include an uncured or partially cured layer and other adhesion-promoting features as discussed, for example, in U.S. Pat. No. 6,030,856, the disclosure of which is hereby incorporated by reference herein. Alternatively or additionally, the pad may be provided with a thin layer of a flowable adhesive on one or both surfaces, and this layer may be a non-uniform layer as described in U.S. Pat. No. 5,548,091, the disclosure of which is hereby incorporated by reference herein, to help prevent gas entrapment in the layer during assembly.

The chip 1258 of each unit is aligned with the central region of the associated panel, so that the rows of contacts 1264 are aligned with the bond window 1232 in the panel. The connection section 1240 of each lead is connected to a contact 1264 of the chip. During this process, the connection section of each lead is detached from the anchor section 1244 of the lead by breaking the frangible section 1242 of the lead. This process may be performed as described in the aforementioned U.S. Pat. No. 5,489,749 by advancing a tool (not shown) such as a thermal, thermosonic or ultrasonic bonding tool into the bond window of the panel in alignment with each connection section so that the tool captures the connection section and forces it into engagement with the appropriate contact.

The units are stacked one on top of the other as illustrated in FIG. 24. Each terminal 1222 is connected to the corresponding terminal of the next adjacent unit via a solder ball 1278. The solder balls 1278 serve as conductive elements which join the corresponding terminals of the various units into vertical conductive buses. Each solder ball makes contact with the terminal of one unit through an aperture and with a terminal of the other unit through an aperture in the dielectric layer of the panel 1220 in that unit.

Prior to assembly of the stack, the individual units can be tested in a test socket having contacts corresponding to the locations of the terminals. Typically, the solder balls are bonded to the terminals of each unit so that they project from the first surface of the panel and the unit is tested with the solder balls in place. For example, the test socket may have openings adapted to engage the solder balls. Because all of the units have terminals and solder balls in the same pattern, the single test socket can be used to test all of the units.

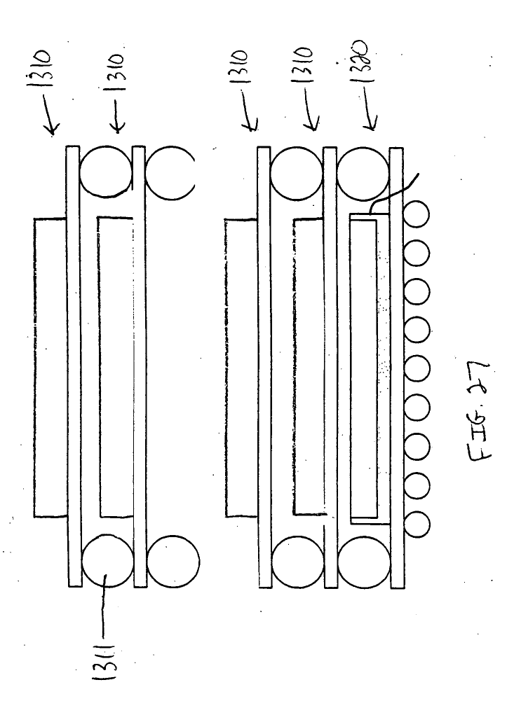

FIGS. 25-27 show a microelectronic assembly similar to that disclosed in commonly assigned U.S. Pat. No. 5,861,666 and U.S. patent application Ser. No. 10/487,482, filed Sep. 17, 2004, the disclosures of which are hereby incorporated by reference herein. Referring to FIGS. 25-27, microelectronic assembly 1300 is preferably made from a number N of prefabricated subassemblies, comprising N-1 subassemblies 1310 (FIG. 26) and bottom subassembly 1320 (FIG. 25). Referring to FIG. 26, subassembly 1310 comprises a semiconductor chip 1301 having opposed surfaces 1302 and 1303, one surface having exposed electrical contacts (not shown), and substrate 1315, such as a flexible dielectric substrate having a first surface 1316 and a second surface 1317. Chip 1301 is mounted on first surface 1316 of substrate 1315 and the contacts are electrically connected to conductors (not shown) on a surface of substrate 1315. Fan-out connectors 1311, such as high-melting solder balls, are affixed to the second surface 1317 of substrate 1315 (the side opposite chip 1301). Referring to FIG. 25, the bottom-most subassembly 1320 comprises an encapsulated microelectronic element 1301′, encapsulant 1304 and substrate 1325 having top surface and bottom surface 1327. A plurality of joining units 1321 are affixed to second surface 1327 (the side opposite from microelectronic element 1301) of substrate 1325. The encapsulant 1304 is preferably compliant so as to allow for relative movement between terminals 1321 and chip 1301′ during thermal cycling. Bottom subassembly 1320 is adapted to serve as the bottom-most unit of stack 1300 and may be affixed directly to a printed circuit board or to a second microelectronic assembly.

Referring to FIG. 27, when subassemblies 1310 and 1320 are stacked, fan-out connectors 1311 electrically interconnect the subassemblies within the stack, thereby acting as vertical conductors. To allow stacking, fan-out connectors 1311 of each subassembly 1310 must be positioned outside of the region of substrate 1315 of the next lower subassembly occupied by chip 1301. Typically, this requirement results in fan-out connectors 1311 of each subassembly 1310 being disposed in a peripheral region of interposer 1315.

As will be appreciated, numerous variations and combinations of the features discussed above can be utilized without departing from present invention as defined by the claims. For example, certain preferred embodiments above depict a stacked microelectronic assembly which is four chips high, however, more chips or fewer chips may be used in accordance with the chip stacking methods of the present invention. Accordingly, the foregoing description of the preferred embodiments should be taken by way of illustration rather than by way of limitation of the present invention.

1. A method of making a stacked microelectronic assembly comprising:
a) providing a flexible substrate having first and second ends, said flexible substrate having a plurality of attachment sites located between said first and second ends thereof including a first one of said attachment sites located adjacent the first end of said flexible substrate, said flexible substrate including conductive terminals accessible at a surface of said flexible substrate and wiring connected to said terminals;
b) providing a compliant layer over said first attachment site;
c) assembling a plurality of microelectronic elements over said attachment sites, wherein a first one of said microelectronic elements engages said compliant layer and is movable relative to said flexible substrate;
d) electrically interconnecting said microelectronic elements and said wiring;
e) folding said flexible substrate and stacking at least some of said microelectronic elements in generally vertical alignment with one another so that said first one of said microelectronic elements engaging said compliant layer is disposed at a bottom of said stacked assembly;
f) maintaining said stacked microelectronic elements in said substantially vertical alignment, wherein said conductive terminals are exposed at the bottom end of said stacked assembly.

2. The method as claimed in claim 1, wherein said wiring includes flexible leads extending to said attachment sites, the electrically interconnecting step including electrically connecting said microelectronic elements and said flexible leads.

3. The method as claimed in claim 1, wherein said flexible substrate includes a polymeric material and has a thickness between approximately 25-75 microns.

4. The method as claimed in claim 1, wherein said wiring interconnects at least some of said microelectronic elements with one another.

5. The method as claimed in claim 2, wherein the assembling step includes aligning contacts on a front face of said microelectronic elements with ends of said flexible leads at said attachment sites.

6. The method as claimed in claim 1, wherein the step of providing a compliant layer includes providing compliant pads at the one of said attachment sites before the assembling step, said compliant pads defining channels therebetween.

7. The method as claimed in claim 6, further comprising introducing a curable liquid encapsulant between the one of said microelectronic element and the one of said attachment sites and through the channels between said compliant pads; and curing said encapsulant to provide said compliant layer.

8. The method as claimed in claim 1, wherein the stacking step includes grouping at least some of said microelectronic elements in pairs and juxtaposing said paired microelectronic elements with one another.

9. The method as claimed in claim 8, wherein each said microelectronic element includes a front contact bearing surface and a back surface remote therefrom, at least some of said microelectronic elements being assembled to the flexible substrate with the front contact bearing surfaces facing toward said attachment sites and the back surfaces facing away from said attachment site.

10. The method as claimed in claim 9, wherein the juxtaposing step includes abutting said back surfaces of said paired microelectronic elements with one another.

11. The method as claimed in claim 10, further comprising applying an adhesive between the back surfaces of said paired microelectronic elements before the abutting step.

12. The method as claimed in claim 11, wherein said adhesive includes a thermally conductive material.

13. The method as claimed in claim 1, wherein the maintaining step includes providing a support structure in contact with said stacked microelectronic elements.

14. The method as claimed in claim 13, wherein said support structure includes a bracket abutting against the top of said stacked microelectronic elements.

15. The method as claimed in claim 10 further comprising providing thermally conductive sheets between the back surfaces of said paired microelectronic elements before the abutting step.

16. A stacked microelectronic assembly comprising:
a flexible substrate having a plurality of attachment sites, said flexible substrate including conductive terminals accessible at a surface thereof, wiring connected to said terminals and flexible leads connected to said wiring and extending to said attachment sites;
a plurality of microelectronic elements assembled to said attachment sites and electrically connected to said leads;
a compliant layer disposed between one of said microelectronic elements and one of said attachment sites, wherein the one of said microelectronic elements is movable relative to said flexible substrate;
said flexible substrate being folded so that at least some of said microelectronic elements are stacked in substantially vertical alignment with one another, the one of said microelectronic elements being positioned at a bottom end of said stacked assembly; and
a securing element maintaining said stacked microelectronic elements in substantially vertical alignment with one another, wherein said conductive terminals are exposed at the bottom end of said stacked assembly.

17. The assembly as claimed in claim 16, wherein said flexible substrate includes a polymeric material and has a thickness between approximately 25 and 60 microns.

18. The assembly as claimed in claim 16, wherein at least one of said microelectronic elements is a semiconductor chip.

19. The assembly as claimed in claim 16, wherein said wiring layer interconnects at least some of said microelectronic elements with one another.

20. The assembly as claimed in claim 16, wherein said flexible substrate is folded in a S-shaped pattern.

21. The assembly as claimed in claim 16, wherein said flexible substrate is folded in a spiral pattern.

22. The assembly as claimed in claim 16, further comprising a rigid element supporting said conductive terminals at the bottom of said stacked assembly.

23. The assembly as claimed in claim 16, wherein said conductive terminals are electrically connected to at least some of said flexible leads.

24. The assembly as claimed in claim 16, wherein said conductive terminals are electrically interconnected to an external circuit element for interconnecting said microelectronic elements and said external circuit element.

25. The assembly as claimed in claim 16, wherein said compliant layer includes a plurality of compliant pads defining channels therebetween.

26. The assembly as claimed in claim 25, wherein each said microelectronic element includes a front contact bearing surface facing said attachment site and a back surface facing away from said attachment site.

27. The assembly as claimed in claim 26, wherein at least some of said stacked microelectronic elements are grouped in pairs, the back surfaces of said paired microelectronic elements being juxtaposed with one another.

28. The assembly as claimed in claim 27, further comprising an adhesive between the back surfaces of said paired microelectronic elements.

29. The assembly as claimed in claim 28, wherein said flexible substrate overlaps upon itself at overlapping sections of said flexible substrate and said adhesive is provided between the overlapping sections of said flexible substrate.

30. The assembly as claimed in claim 28, further comprising thermally conductive sheets between the back surfaces of said paired microelectronic elements for transferring heat from said stacked assembly.

31. A method of making a stacked microelectronic assembly comprising:
a) providing a flexible substrate having a plurality of attachment sites, said flexible substrate including conductive terminals accessible at a surface thereof and wiring connected to said terminals;
b) assembling a plurality of microelectronic elements over said attachment sites;
c) electrically interconnecting said microelectronic elements and said wiring;
d) providing an encapsulant layer between said microelectronic elements and said attachment sites;
e) folding said flexible substrate and stacking at least some of said microelectronic elements in generally vertical alignment with one another, wherein a first one of said microelectronic elements is disposed at a bottom of said stacked assembly, and wherein a region of said encapsulant layer adjacent said first microelectronic element is more compliant than said encapsulant layer adjacent the other said microelectronic elements.

32. The assembly as claimed in claim 31, further comprising maintaining said stacked microelectronic elements in said substantially vertical alignment, wherein said conductive terminals are exposed at the bottom end of said stacked assembly.

33. A stacked microelectronic assembly comprising:
a dielectric element having an upwardly-facing first surface and a downwardly facing second surface and having conductive terminals exposed at said second surface;
a first microelectronic element overlying said first surface of said dielectric element;
a second microelectronic element overlying said first microelectronic element;
a first encapsulant layer between said first microelectronic element and said first surface of said dielectric layer;
a second encapsulant layer between said first and second microelectronic elements, wherein said first encapsulant layer is more compliant than said second encapsulant layer so that one or more of said conductive terminals underlying said first microelectronic element are movable relative to said first microelectronic element.

34. The assembly as claimed in claim 33, wherein said first and second microelectronic elements are electrically interconnected with said conductive terminals of said dielectric element.

35. The assembly as claimed in claim 33, further comprising a second dielectric element between said second encapsulant layer and said first microelectronic element.

36. A microelectronic assembly including a plurality of microelectronic subassemblies, each said microelectronic subassembly comprising:
a dielectric substrate having a top surface;
a microelectronic element mounted over said dielectric substrate, wherein said microelectronic element is electrically interconnected with said dielectric substrate;
an encapsulant layer provided over the top surface of said dielectric substrate between said microelectronic element and said dielectric substrate, wherein said microelectronic subassemblies are stacked one atop another, and wherein said encapsulant layer of a bottom one of said stacked subassemblies is more compliant than said encapsulant layers of said stacked subassemblies above said bottom subassembly.

37. The microelectronic assembly as claimed in claim 36, wherein said dielectric substrates are flexible dielectric substrates.

38. The microelectronic assembly as claimed in claim 36, wherein the microelectronic element is a semiconductor chip having a front face with contacts and a back face remote therefrom.

39. The microelectronic assembly as claimed in claim 36, wherein said first encapsulant layer comprises a plurality of compliant pads spaced from one another for defining channels therebetween.

40. A microelectronic assembly with a basal compliant layer comprising:
microelectronic subassemblies stacked one atop another, each said subassembly comprising:
a dielectric substrate having a top surface;
a microelectronic element mounted over the top surface of said dielectric substrate;
an encapsulant layer between said microelectronic element and the top surface of said dielectric substrate;
wherein the encapsulant layer of a bottom one of said stacked microelectronic subassemblies is more compliant than the encapsulant layers of said other microelectronic subassemblies of said stacked microelectronic assembly.

41. The assembly as claimed in claim 40, wherein two or more of said stacked microelectronic subassemblies are electrically interconnected with one another.

42. The assembly as claimed in claim 40, wherein said dielectric substrate of said bottom subassembly has conductive terminals accessible at a bottom surface thereof.

43. The assembly as claimed in claim 42, wherein at least one of said stacked subassemblies is electrically interconnected with said conductive terminals.

44. The assembly as claimed in claim 40, wherein said encapsulant layer of said bottom subassembly comprises a plurality of compliant pads.
